(19) United States
(12) Patent Application Publication
(10) Pub. No.: US 2024/0105782 A1
(43) Pub. Date: Mar. 28, 2024

(54) MONOCRYSTALLINE SILICON CARBIDE SUBSTRATE, METHOD FOR MANUFACTURING THE SAME, AND SEMICONDUCTOR DEVICE

(71) Applicants: TANKEBLUE SEMICONDUCTOR CO., LTD., Beijing (CN); XINJIANG TANKEBLUE SEMICONDUCTOR CO. LTD, Xinjiang (CN); JIANGSU TANKEBLUE SEMICONDUCTOR CO., LTD, Jiangsu (CN)

(72) Inventors: Yanfang LOU, Beijing (CN); Chunjun LIU, Beijing (CN); Guangming WANG, Beijing (CN); Jing YAO, Beijing (CN); Qing YONG, Beijing (CN); Tonghua PENG, Beijing (CN); Jian YANG, Beijing (CN)

(21) Appl. No.: 18/330,156

(22) Filed: Jun. 6, 2023

(30) Foreign Application Priority Data
Feb. 15, 2022 (CN) 202210138486.X

(51) Int. Cl. H01L 29/32; C30B 23/02; C30B 29/36; C30B 33/02; H01L 29/16

(52) U.S. Cl. CPC H01L 29/32; C30B 23/025; C30B 29/36; C30B 33/02; H01L 29/1608; B28D 5/045

(57) ABSTRACT

A monocrystalline SiC substrate comprising a first surface and a second surface. The first surface comprises pinning regions and a device region. Each of the pinning regions is configured to provide a potential well which is capable to attract dislocations from a region surrounding said pinning region. The device region is configured to provide a part of the monocrystalline SiC substrate for manufacturing a semiconductor device. The device region is surrounded by the pinning regions, and a density of dislocations in a central portion of the device region is smaller than a density of dislocations in an edge of the device region due to the pinning regions. The pinning regions surrounding the device region attracts dislocations of the device region into the edge portion, so that the density of dislocations in the central portion is reduced. A yield of the semiconductor devices is improved.

### FIELD

The present disclosure relates to the technical field of manufacturing monocrystalline silicon carbide, and in particular to a monocrystalline silicon carbide substrate, a method for manufacturing the monocrystalline silicon carbide substrate, and a semiconductor device.

### BACKGROUND

Silicon carbide (SiC) belongs to third-generation wide band-gap materials, and develops rapidly with continuous innovation of semiconductor technology due to excellent material properties and promising application potentials of SiC devices. Manufacture of SiC crystals and researches on relevant devices have been a hot topic throughout the world for a long time. Monocrystalline SiC has excellent properties such as a wide band gap, a high breakdown electric field, high thermal conductivity, high saturated electron drift velocity, high chemical stability, and strong radiation resistance. Thus, it has become a preferable material for high-power high-frequency semiconductor devices having a high requirement of thermal resistance and radiation resistance.

Dislocations are a kind of main defects in a monocrystalline SiC substrate, and have a significant impact on performances of the semiconductor device manufactured from the monocrystalline SiC substrate. Currently, a density of dislocations is still high in commercial semiconductor devices manufactured from the monocrystalline SiC substrate. Although such density is gradually decreasing in recent years due to a progress in techniques, improvement in a yield of the related semiconductor devices is still not satisfactory.

Therefore, how to improve the yield of the related semiconductor devices is an urgent technical issue to be addressed by those skilled in the art.

### SUMMARY

In view of the above, an objective of the present disclosure is to provide a monocrystalline SiC substrate. Thereby, semiconductor devices can have an improved yield when manufactured from the monocrystalline SiC substrate.

Another objective of the present disclosure is to provide a method for manufacturing the monocrystalline SiC substrate.

Another objective of the present disclosure is to provide a semiconductor device manufactured from the monocrystalline SiC substrate.

In order to achieve the above objectives, following technical solutions are provided according to embodiments of the present disclosure.

A monocrystalline SiC substrate is provided according to an embodiment of the present disclosure. The monocrystalline SiC substrate comprises a first surface and a second surface. The first surface comprises pinning regions and a device region. Each of the pinning regions is configured to provide a potential well which is capable to attract dislocations from a region surrounding said pinning region. The device region is configured to provide a part of the monocrystalline SiC substrate for manufacturing a semiconductor device. The device region is surrounded by the pinning regions, and a density of dislocations in a central portion of the device region is smaller than a density of dislocations in an edge of the device region due to the pinning regions.

In an embodiment, the pinning regions are equally separated on the first surface, and the pinning regions which surround the device region are equally separated along a peripheral of the device region.

In an embodiment, each of the pinning regions is a square of which a side length ranges from 40 μm to 100 μm. The device region is a rectangular, and four of the pinning regions are disposed at four vertices, respectively, of the device region.

In an embodiment, the device region is a square.

In an embodiment, the device region is utilized for manufacturing one or more semiconductor devices.

In an embodiment, a density of dislocations in the device region is less than 3000/cm².

In an embodiment, a density of threading screw dislocations in the device region is less than 500/cm².

In an embodiment, a density of threading edge dislocations in the device region is less than 1500/cm².

In an embodiment, a density of basal plane dislocations in the device region is less than 1000/cm².

A method for manufacturing a monocrystalline SiC substrate is further provided according to embodiments of the present disclosure. The method is for manufacture one or more of the monocrystalline SiC substrates in the foregoing technical solutions. The method comprises: processing a growth surface of a seed crystal, where a shape and a distribution state of the pinning regions of the monocrystalline SiC substrate are determined, and a pattern is formed on the growth surface of the seed crystal based on the shape of the pinning regions; annealing the processed seed crystal at a first preset temperature for a first preset period under protection of an inert gas; growing a SiC monocrystal by using the annealed seed crystal, which is disposed in a furnace, through physical vapor transport; cutting the grown SiC monocrystal into one or more crystal plates with a required thickness through a multi-wire sawing; and grinding, polishing, and rinsing the one or more crystal plates to obtain one or more of the monocrystalline SiC substrates in the foregoing technical solutions.

In an embodiment, processing the growth surface of the seed crystal comprises: forming the pattern on the growth surface of the seed crystal through one or more of coating, evaporation, magnetron sputtering, immersion plating, and pasting.

In an embodiment, the pattern is made of graphite.

In an embodiment, the pattern is made of one or more of niobium, rhenium, osmium, tantalum, molybdenum, tungsten, and iridium.

In an embodiment, the pattern is made of one or more of niobium carbide, rhenium carbide, osmium carbide, tantalum carbide, molybdenum carbide, tungsten carbide, and iridium carbide.

In an embodiment, the first preset temperature ranges from 800° C. to 1000° C., and the first preset period ranges from 20 minutes to 40 minutes.

In an embodiment, the inert gas is argon.

A semiconductor device is further provided according to embodiments of the present disclosure. The semiconductor device is manufactured from one or more of the monocrystalline SiC substrates in the foregoing technical solutions.

In an embodiment, an effective region of the semiconductor device is manufactured from the central portion of the device region in the monocrystalline SiC substrate, and the effective region is a region of the semiconductor device on which a voltage is applied.

The foregoing technical solutions show a following difference between the monocrystalline SiC substrate according to embodiments of the present disclosure and that in conventional technology. Herein the pinning region is provided on the first surface of the monocrystalline SiC substrate for attracting, through the potential well in the pinning region, dislocations from the region surrounding the pinning region toward the pinning region. There are multiple pinning regions on the first surface. The device region is further provided on the first surface for manufacturing the semiconductor device from the monocrystalline SiC substrate. The pinning regions are arranged around the device region, such that the density of dislocations in the central portion of the device region is less than that in the edge portion of the device region. Since the pinning regions are intentionally disposed around the device region, the dislocations originally in the device region can be moved into the edge portion of the device region, thereby reducing the density of dislocations in the central portion of the device region. Such portion having a lower density of dislocations in the device region is utilized for manufacturing a voltage-applied region, i.e., the effective region, of the semiconductor device, so that a density of dislocations in the effective region can be significantly reduced. Hence, a failure probability of the effective region under a voltage is reduced, improving a yield of the semiconductor devices.

### BRIEF DESCRIPTION OF THE DRAWINGS

For clearer illustration of the technical solutions according to embodiments of the present disclosure or conventional techniques, hereinafter briefly described are the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 is a schematic diagram of circular pinning regions according to an embodiment of the present disclosure.

FIG. 2 is a schematic diagram of parallel stripe pinning regions according to an embodiment of the present disclosure.

FIG. 3 is a schematic diagram of crossing stripe pinning regions according to an embodiment of the present disclosure.

FIG. 4 is a flow chart of a method for manufacturing a monocrystalline SiC substrate according to an embodiment of the present disclosure.

### REFERENCE NUMERALS

10 First surface, 110 Pinning region, 120 Device region.

### DETAILED DESCRIPTION

A core solution of the present disclosure is providing a monocrystalline SiC substrate, such that semiconductor devices can have an improved yield when manufactured from the monocrystalline SiC substrate.

Another core solution of the present disclosure is providing a method for manufacturing the monocrystalline SiC substrate.

Another core solution of the present disclosure is providing a semiconductor device manufactured from the monocrystalline SiC substrate.

In order to facilitate those skilled in the art understanding solutions of the present disclosure better, hereinafter embodiments of the present disclosure are described in conjunction with the drawings. The following embodiments do not put any limitation on content as recited in the claims. Further, what is described in the following embodiments may not be necessary for the solutions as defined in the claims.

Dislocations are a kind of main defects in conventional monocrystalline SiC substrates, and have a significant impact on performances of the semiconductor device manufactured from the monocrystalline SiC substrate. Currently, a density of dislocations is still high in commercial semiconductor devices manufactured from the monocrystalline SiC substrate. Although such density is gradually decreasing in recent years due to a progress in techniques, improvement in a yield of the related semiconductor devices is still not satisfactory.

Researches on correlation between failure of a semiconductor device and dislocations in a monocrystalline SiC substrate reveal that a region having a high density of dislocations may not fail while a region having a low density of dislocations may fail in the semiconductor device. Moreover, besides an average density of dislocations, a spatial distribution of the dislocations also accounts for a failure of the semiconductor device. A region of a semiconductor device on which a voltage is applied is called an effective region of the semiconductor device. It is revealed that in the semiconductor device, a performance of the effective region is quite sensitive to the dislocations, while that of a region away from the effective region is less sensitive to the dislocations. Therefore, a yield of the semiconductor devices cannot be significantly improved through reducing an overall density of dislocations of the semiconductor device, and may be improved through controlling the distribution of the dislocations.

Herein a novel means is proposed for controlling the distribution of the dislocations in the monocrystalline SiC substrate. A technical prejudice that all dislocations in the monocrystalline SiC substrate should to be eliminated is overcome. Instead, a pinning region 110 is intentionally arranged on the monocrystalline SiC substrate to control the distribution of dislocations in the monocrystalline SiC substrate. Specific details may refer to following embodiments.

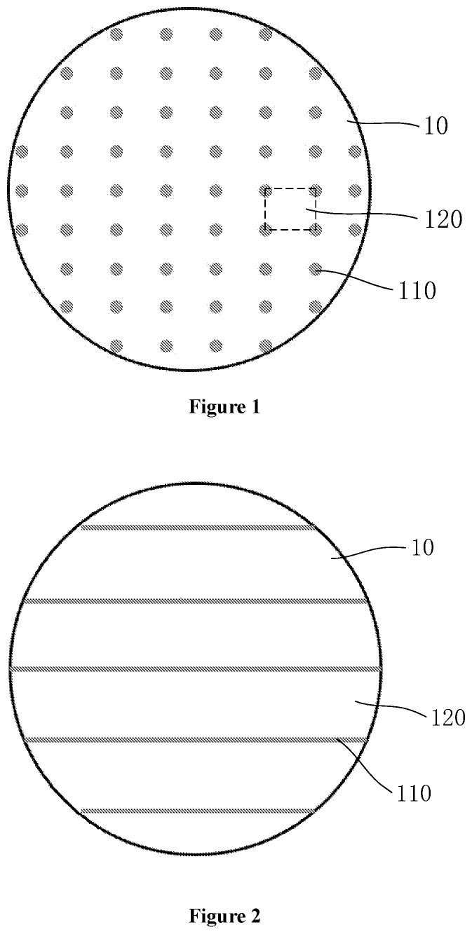

Reference is made to FIG. 1. A monocrystalline SiC substrate is provided according to an embodiment of the present disclosure. The monocrystalline SiC substrate comprises a first surface 10 and a second surface. The first surface 10 of the monocrystalline SiC substrate is for manufacturing a semiconductor device. The second surface is a fixing surface, i.e., configured to fix the monocrystalline SiC substrate to processing equipment. The first surface 10 comprises a pinning region 110 and a device region 120. The pinning region 110 provides an intentionally formed potential well. Thereby, the dislocations are apt to be stationed when moving inside the monocrystalline SiC substrate under a thermal driving force and approaching the pinning region 110. Accordingly, the dislocations are concentrated toward the pinning region 110. Multiple pinning regions 110 may be arranged on the first surface 10. The device region 120 is configured to provide a part of the monocrystalline SiC substrate for manufacturing the semiconductor device. The device region 120 is surrounded by the pinning regions 110, such that the dislocations are attracted toward an edge of the device region 120, which reduces a density of dislocations at a central portion of the device region 120. Hence, the central portion of the device region 120 is the monocrystalline SiC substrate having a low density of dislocations. Such region is utilized to fabricate a region of the semiconductor device on which a voltage is applied, that is, to fabricate the effective region of the semiconductor device, which can reduce the density of dislocations in the effective region significantly. Thus, a failure probability of the effective region is reduced, improving the yield of the semiconductor devices.

Herein the monocrystalline SiC substrate is provided according to embodiments of the present disclosure. The pinning region 110 and the device region 120 are arranged on the first surface 10 of the monocrystalline SiC substrate, and the dislocations are concentrated toward the pinning region 110 through the potential well that is intentionally arranged. The potential well is capable to attract the dislocations in a region around the potential well toward the potential well under the thermal driving force, such that the dislocations are concentrated toward the potential well and are hard to escape. As a result, the dislocations are concentrated at a location corresponding to the potential well. In addition, the pinning regions 110 surround the device region 120, such that the dislocations in the device region 120 concentrate toward the edge of the device region 120. Give that a total quantity of the dislocations is constant in the device region 120, the density of dislocations in the central portion can be significantly reduced. The monocrystalline SiC substrate in the central portion is utilized to fabricate the region of the semiconductor device on which a voltage is applied, i.e., the effective region of the semiconductor device, which can reduce the density of dislocations in the effective region significantly. Thus, a failure probability of the effective region is reduced, improving the yield of the semiconductor devices significantly.

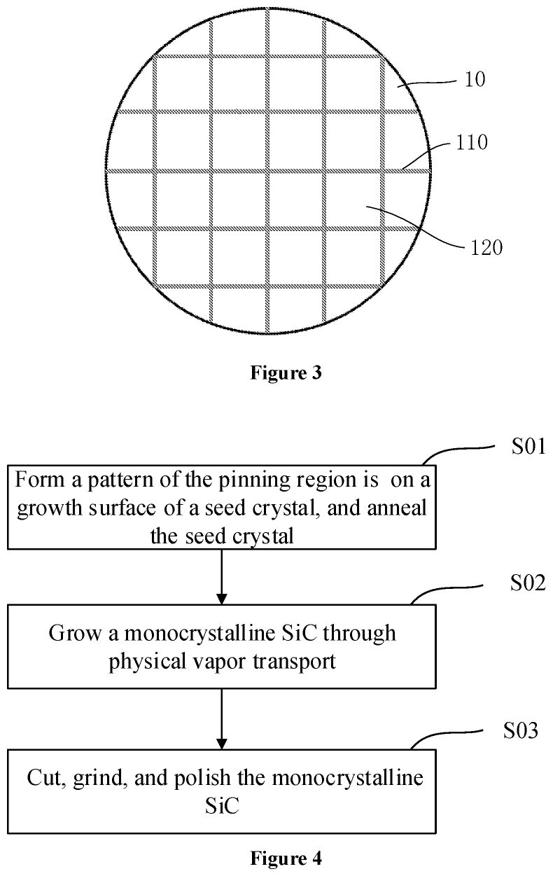

Reference is further made to FIGS. 1, 2, and 3. The pinning region 110 may be of any shape in the monocrystalline SiC substrate. Multiple pinning regions 110 are equally separated on the first surface 10, that is, along each direction, every pair of adjacent pinning regions 110 are separated by the same distance. The pinning regions 110 surrounding the device region are equally separated along an edge of the device region 120, such that the dislocations in the device region 120 are uniformed attracted to the edge region when reducing the density of dislocations in the central portion. An edge of the device region 120 may abut a single pinning region 110 or abut multiple pinning regions 110.

The pinning region 110 may be rectangular, square, circular, triangular, or a stripe. The multiple pinning regions 110 may be arranged in an array.

In an embodiment, each of the pinning regions 110 is a square, of which a side length ranges from 40 μm to 100 μm. As a preferable example, the side length of the pinning region 110 is 60 μm. The pinning regions 110 are arranged along two perpendicular directions on the first surface 10, and are uniformly distributed throughout the first surface 10. The device region 120 is rectangular, and four pinning regions 110 are arranged at four vertices, respectively, of the rectangular device region 120.

The device region 120 may cover the whole region surrounded by the four pinning regions 110, or cover a part of the region surrounded by the four pinning regions 110. As long as the central portion of the device region 120 is located at a center of the region surrounded by the four pinning regions 110, the density of dislocations in the central portion of the device region 120 can be ensured to be less than the density of dislocations in the edge portion of the device region 120. Preferably, the device region 120 covers the whole region surrounded by the four pinning regions 110.

Reference is made to FIG. 2. In another embodiment, the pinning regions 110 are stripes, which are equally separated along a vertical direction, on the first surface 10. Regions between adjacent stripe pinning regions 110 serve as the device regions 120. The dislocations in each device region 120 are concentrated in a region adjacent to the upper stripe pinning region 110 and a region adjacent to a lower stripe pinning region 110. Thereby, the density of dislocations in the central portion of the device region 120 is lower than the density of dislocations in the foregoing two regions adjacent to the upper and lower pinning regions 110.

The pinning regions 110 may alternatively be stripe pinning regions 110 that are equally separated along a horizontal direction or a direction of a predetermined angle on the first surface 10. Regions between adjacent stripe pinning regions 110 serve as the device regions 120. The predetermined angle is determined according to a processing requirement.

The foregoing solution may be optimized by setting the device region 120 as a square region. That is, two adjacent pinning regions 110 in a horizontal direction and those in a vertical direction have the same separation distance. Compared with the rectangular device region 120, the pinning regions 110 can be disposed more uniformly surrounding the square device region 120.

In the monocrystalline SiC substrate, the device region 120 may be utilized for manufacturing one or more semiconductor devices.

In an embodiment, the density of dislocations in the device region 120 is less than 3000/cm², preferably less than 1500/cm², and more preferably less than 600/cm².

The dislocations in the device region 120 are categorized into different types comprising threading screw dislocations, threading edge dislocations, and basal plane dislocations. In a preferable embodiment, a total density of dislocations of the foregoing three types is less than 800/cm².

In another embodiment, a density of threading screw dislocations in the device region 120 is less than 500/cm², preferably less than 200/cm², and more preferably less than 100/cm².

In another embodiment, a density of threading edge dislocations in the device region 120 is less than 1500/cm², preferably less than 800/cm², and more preferably less than 300/cm².

In another embodiment, a density of basal plane dislocations in the device region 120 is less than 1000/cm², preferably less than 500/cm², and more preferably less than 200/cm².

A method for manufacturing a monocrystalline SiC substrate is further provided according to embodiments of the present disclosure. The method is for manufacturing the monocrystalline SiC substrate according to any foregoing embodiment. Reference is made to FIG. 4, where the method comprises following steps S01 to S03.

In step S01, a pattern of the pinning region is formed on a growth surface of a seed crystal, and then the seed crystal is annealed.

In step S02, a monocrystalline SiC is grown through physical vapor transport.

In step S03, the monocrystalline SiC is subject to cutting, grinding, and polishing.

In the step S01, a shape and a distribution of the pinning region 110 on the monocrystalline SiC substrate are first determined, and a pattern is formed on the growth surface of the seed crystal based on the shape of the pinning region 110. Then, the processed seed crystal is annealed. In the annealing, the seed crystal with the pattern is disposed at a first preset temperature for a first preset period under protection of an inert gas, and then is slowly cooled down. An objective of the annealing is to achieve a firm bound between the pattern and the seed crystal more firmly.

In the step S02, the seed crystal after the step S01 is utilized to grow the monocrystalline SiC. The grown monocrystalline SiC is a crystal comprising the pinning region 110.

In the step S03, the grown monocrystalline SiC are cut into crystal plate(s) having required thickness through multi-wire sawing. Then, the crystal plate(s) are grounded, polished, and rinsed to obtain the monocrystalline SiC substrate according to any foregoing embodiment.

The foregoing technical solutions may be further optimized. In the step S01, the pattern is formed on the growth surface of the seed crystal through one or more of coating, evaporation, magnetron sputtering, immersion plating, and pasting. In a preferable embodiment, the pattern is formed on the growth surface of the seed crystal through the magnetron sputtering. A process of the coating, the evaporation, the magnetron sputtering, the immersion plating, and the pasting may refer to common techniques, and is not illustrated herein.

In an embodiment, in the step S01, a material of the pattern formed on the growth surface of the seed crystal is graphite. The graphite pattern has high temperature resistance, and has an element existing in the SiC crystal. Hence, no impurity element would be introduced.

In another embodiment, in the step S01, a material of the pattern formed on the growth surface of the seed crystal comprises one or more of niobium, rhenium, osmium, tantalum, molybdenum, tungsten, and iridium.

In another embodiment, in the step S01, a material of the pattern formed on the growth surface of the seed crystal comprises one or more of niobium carbide, rhenium carbide, osmium carbide, tantalum carbide, molybdenum carbide, tungsten carbide, and iridium carbide.

In another embodiment, in the step S01, a material of the pattern formed on the growth surface of the seed crystal comprises one or both of refractory metal and refractory metal carbide.

The foregoing technical solutions may be further optimized. In the step S01, the first preset temperature ranges from 800° C. to 1000° C. In a preferable embodiment, the first preset temperature is 900° C. The first preset period ranges from 20 minutes to 40 minutes. In a preferable embodiment, the first preset period is 30 minutes.

In an embodiment, in the step S01, the inert gas is argon for the annealing.

A semiconductor device is further provided according to embodiments of the present disclosure. The semiconductor device is manufactured from the monocrystalline SiC substrate according to any foregoing embodiment.

Herein the effective region of the semiconductor device is manufactured from the monocrystalline SiC substrate in the central portion of the device region 120, so that the density of dislocations in the effective region is ensured to be less than the density of dislocations at other positions of the semiconductor device. A failure probability of the semiconductor device is reduced, and a yield of semiconductor devices is improved.

For clearer understanding of the foregoing method and the improvement in the yield of semiconductor devices, hereinafter a specific embodiment is provided for detailed illustration.

A monocrystalline SiC substrate is manufactured through the method according to an embodiment of the present disclosure. In this embodiment, a piece of a 4-degree 6-inch SiC seed crystal is selected for manufacturing the monocrystalline SiC substrate. The method comprises the following steps I to V.

In step I, the pattern for the pinning region 110 is formed on the growth surface of the seed crystal. The pattern is formed by using graphite paper as a mask. A layer of pinning regions 110, which are made of a carbon film and are as an array, is formed on the growth surface through magnetron sputtering. Each pinning region 110 is a circle of which a diameter is 50 μm. Two adjacent pinning regions 110 are separated by a distance of 2.4 mm. In the pattern, the pinning regions 110 are uniformly distributed throughout the growth surface of the seed crystal.

In step II, the seed crystal is annealed, where the seed crystal having the pattern is annealed at 900° C. for 30 minutes under protection of argon.

In step IV, after the seed crystal is annealed, the monocrystalline SiC is grown through physical vapor transport (PVT). A process of the PVT may refer to common techniques, and is not illustrated herein.

In step V, the grown monocrystalline SiC is cut into 6-inch SiC crystal plates, each of which is 350 μm in thickness through multi-wire sawing. Then, a SiC crystal plate is etched by potassium hydroxide (KOH) to detect distribution of dislocations. It is revealed that the density of dislocations in the pinning region 110 is 9552/cm², and the density of dislocations in the device region 120 is 2360/cm².

In conventional technology, monocrystalline SiC is grown without forming the pattern on the growth surface of a seed crystal, i.e., the 4-degree 6-inch SiC seed crystals directly disposed at a top of a crucible, and the monocrystalline SiC is grown through the PVT to obtain a 6-inch SiC crystal. Similarly, the 6-inch SiC crystal is cut into a 6-inch SiC crystal plate having a thickness of 350 μm through the multi-wire sawing, and is etched by potassium hydroxide (KOH) for detection of distribution of dislocations. It is revealed that the dislocations are uniformly distributed with an average density of 6385/cm².

The above comparison shows that in the monocrystalline SiC substrate manufactured through the method according to embodiments of the present disclosure, the density of dislocations in the central portion of the device region 120 is significantly less than the density of dislocations in the edge portion of the device region 120, and is further significantly less than the density of dislocations on a surface of the monocrystalline SiC substrate manufactured through conventional technology. Hence, the method according to embodiments of the present disclosure achieves control on the distribution of dislocations in the monocrystalline SiC substrate.

For clearer understanding of the improvement in the yield of the semiconductor devices according to embodiments of the present disclosure, hereinafter an embodiment concerning two groups of semiconductor devices is provided for detailed illustration.

In a first group, ten pieces of the monocrystalline SiC substrates according to embodiments of the present disclosure are provided for manufacturing semiconductor devices. Each semiconductor device in a same batch has a dimension of 2.4 mm×2.4 mm, which is identical to a dimension of the single device region 120. The effective region of the semiconductor device is located at the central portion of the device region 120. Thereby, ten pieces of semiconductor products are obtained.

In a second group, ten pieces of the monocrystalline SiC substrates according to embodiments of the present disclosure are provided for manufacturing semiconductor devices. Each semiconductor device in a same batch has a dimension of 2.4 mm×2.4 mm, and each device region 120 is capable to accommodate four semiconductor devices. That is, a single device region 120 corresponds to four effective regions. The semiconductor devices are arranged in an array at the central portion of the device region 120. Thereby, ten pieces of semiconductor products are obtained.

In a third group, ten pieces of monocrystalline SiC substrates manufactured through conventional technology are provided for manufacturing semiconductor devices. Each semiconductor device in a same batch has a dimension of 2.4 mm×2.4 mm.

As a result, a yield of the semiconductor devices in the first group is higher than that in the third group by 26%, and a yield of the semiconductor devices in the second group is higher than that in the third group by 18%. This embodiment indicates that the semiconductor devices manufactured according to embodiments of the present disclosure have a significantly improved yield. The technical solutions herein has a great technical advantage and a significant economic potential compared to conventional technology.

In specification, claims, and drawings of the present disclosure, the terms “first”, “second”, and the like are intended to distinguish similar objects but do not necessarily indicate a specific order or sequence. Moreover, the terms “include”, “comprise”, and any other variants thereof are intended to cover non-exclusive inclusion. For example, a process, a method, a system, a product, or a device that includes a list of steps or units is not necessarily limited to these expressly listed steps or units, but may include another step or another unit that is not expressly listed.

According to the description of the disclosed embodiments, those skilled in the art can implement or use the present disclosure. Various modifications made to these embodiments may be obvious to those skilled in the art, and the general principle defined herein may be implemented in other embodiments without departing from the spirit or scope of the present disclosure. Therefore, the present disclosure is not limited to the embodiments described herein but conforms to a widest scope in accordance with principles and novel features disclosed in the present disclosure.

1. A monocrystalline SiC substrate, comprising a first surface and a second surface, wherein:
the first surface comprises pinning regions and a device region;
each of the pinning regions is configured to provide a potential well which is capable to attract dislocations from a region surrounding said pinning region;
the device region is configured to provide a part of the monocrystalline SiC substrate for manufacturing a semiconductor device;
the device region is surrounded by the pinning regions; and
a density of dislocations in a central portion of the device region is smaller than a density of dislocations in an edge of the device region due to the pinning regions.

2. The monocrystalline SiC substrate according to claim 1, wherein the pinning regions are equally separated on the first surface, and the pinning regions which surround the device region are equally separated along a peripheral of the device region.

3. The monocrystalline SiC substrate according to claim 2, wherein:
each of the pinning regions is a square of which a side length ranges from 40 μm to 100 μm; and
the device region is a rectangular, and four of the pinning regions are disposed at four vertices, respectively, of the device region.

4. The monocrystalline SiC substrate according to claim 3, wherein the device region is another square.

5. The monocrystalline SiC substrate according to claim 3, wherein the device region is utilized for manufacturing one or more semiconductor devices.

6. The monocrystalline SiC substrate according to claim 1, wherein a density of dislocations in the device region is less than 3000/cm².

7. The monocrystalline SiC substrate according to claim 1, wherein a density of threading screw dislocations in the device region is less than 500/cm².

8. The monocrystalline SiC substrate according to claim 1, wherein a density of threading edge dislocations in the device region is less than 1500/cm².

9. The monocrystalline SiC substrate according to claim 1, wherein a density of basal plane dislocations in the device region is less than 1000/cm².

10. A method for manufacturing the monocrystalline SiC substrate according to claim 1, comprising:
processing a growth surface of a seed crystal, wherein a shape and a distribution state of the pinning regions of the monocrystalline SiC substrate are determined, and a pattern in formed on the growth surface of the seed crystal based on the shape of the pinning regions;
annealing the processed seed crystal at a first preset temperature for a first preset period under protection of an inert gas;
growing a SiC monocrystal by using the annealed seed crystal, which is disposed in a furnace, through physical vapor transport;
cutting the grown SiC monocrystal into one or more crystal plates with a required thickness through a multi-wire sawing; and
grinding, polishing, and rinsing the one or more crystal plates to obtain one or more of the monocrystalline SiC substrates in the foregoing technical solutions.

11. The method according to claim 10, wherein in processing the growth surface of the seed crystal comprises:
forming the pattern on the growth surface of the seed crystal through one or more of coating, evaporation, magnetron sputtering, immersion plating, and pasting.

12. The method according to claim 10, wherein the pattern is made of graphite.

13. The method according to claim 10, wherein the pattern is made of one or more of niobium, rhenium, osmium, tantalum, molybdenum, tungsten, and iridium.

14. The method according to claim 10, wherein the pattern is made of one or more of niobium carbide, rhenium carbide, osmium carbide, tantalum carbide, molybdenum carbide, tungsten carbide, and iridium carbide.

15. The method according to claim 10, wherein the first preset temperature ranges from 800° C. to 1000° C., and the first preset period ranges from 20 minutes to 40 minutes.

16. The method according to claim 10, wherein the inert gas is argon.

17. A semiconductor device, manufactured from the monocrystalline SiC substrate according to claim 1.

18. The semiconductor device according to claim 17, wherein an effective region of the semiconductor device is manufactured from the central portion of the device region in the monocrystalline SiC substrate, and the effective region is a region of the semiconductor device on which a voltage is applied.
